(19) United States
(12) Patent Application Publication
(10) Pub. No.: US 2013/0221360 A1
(43) Pub. Date: Aug. 29, 2013

(54) THIN FILM TRANSISTOR HAVING ATOMIC-DOPING LAYER

(71) Applicant: JIAN-SHIHN TSANG, Tu-Cheng (TW)

(72) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/457,658

(22) Filed: Apr. 27, 2012

(30) Foreign Application Priority Data
Feb. 29, 2012 (TW) 101106503

(51) Int. Cl. H01L 29/786

(52) U.S. Cl. 257/66; 257/E29.273

(57) ABSTRACT

A thin film transistor includes a substrate, a source electrode and a drain electrode formed on the substrate, a channel layer formed between the source electrode and the drain electrode, an insulative layer covering the channel layer and a gate electrode formed on the insulative layer. An atomic-doping layer is formed in the channel layer. The atomic-doping layer is delta-doping with no more than one layer of atom.

### BACKGROUND

1. Technical Field

The present disclosure relates to thin film transistors, and more particularly, to a thin film transistor having an atomic-doping layer.

2. Description of Related Art

Thin film transistors are used in liquid crystal displays for controlling status of pixels. A conventional thin film transistor includes a substrate, a source electrode and a drain electrode formed on the substrate, a channel layer formed between the source electrode and the drain electrode, and a gate electrode formed on the channel layer. The gate electrode controls conduction states of the channel layer, thereby switching the thin film transistor between on and off status.

Nowadays, transparent conductive oxide semiconductor materials are used to form the channel layer under a low temperature. The thin film transistor may have a disadvantage that the conductivity of the channel layer is affected by many factors, such as temperature and humidity of manufacturing environment and manufacturing technologies, and particularly, the distribution of oxygen vacancies and metal cations of the channel layer. It may be difficult to ensure high conductivity of the channel layer.

What is needed, therefore, is a thin film transistor having an atomic-doping layer which can overcome the above described disadvantage.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross section of a thin film transistor in accordance with a first embodiment of the present disclosure.

FIG. 2 is a cross section of a thin film transistor in accordance with a second embodiment of the present disclosure.

FIG. 3 is a cross section of a thin film transistor in accordance with a third embodiment of the present disclosure.

FIG. 4 is a cross section of a thin film transistor in accordance with a forth embodiment of the present disclosure.

### DETAILED DESCRIPTION OF THE EMBODIMENTS

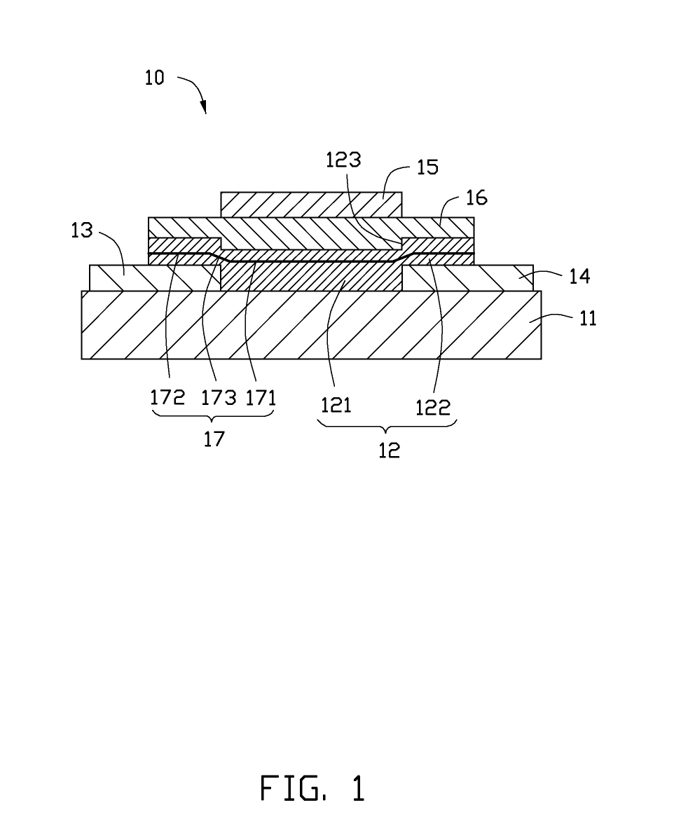

Referring to FIG. 1, a thin film transistor 10 in accordance with a first embodiment of the present disclosure is shown. The thin film transistor 10 includes a substrate 11, a source electrode 13 and a drain electrode 14 formed on the substrate 11, a channel layer 12 formed between the source electrode 13 and the drain electrode 14, an insulative layer 16 formed on the channel layer 12 and a gate electrode 15 formed on the insulative layer 16.

The substrate 11 is flat. The substrate 11 may be made of glass, silicon, PC (polycarbonate), PMMA (polymethyl methacrylate), metal, paper or other suitable materials.

The source electrode 13 and the drain electrode 14 are formed on two opposite sides of a top face of the substrate 11. The source electrode 13 is spaced a gap (not labeled) from the drain electrode 14 so that the source electrode 13 and the drain electrode 14 are not directly connected to each other. The source electrode 13 and the drain electrode 14 have the same thickness. The source electrode 13 and the drain electrode 14 may be made of metal or transparent conductive oxide, such as Mo, Al, Cu, Ti, Pd, Nd, ITO (InSnOx), or the like.

The channel layer 12 is formed in the gap and partially covers the source electrode 13 and the drain electrode 14. The channel layer 12 may be made of a transparent conductive oxide semiconductor material such as IGZO, IZO, AZO, GZO, ITO, GTO, ATO, TiOₓ, SnOₓ, InOₓ, GaOₓ, GdOₓ, or ZnO. The channel layer 12 may be doped with carrier such as electron or hole so that the channel layer 12 represents n-type or p-type. The channel layer 12 includes a central portion 121 filling the gap and two lateral portions 122 respectively overlaying confronting inner ends of the source electrode 13 and the drain electrode 14. The central portion 121 has a thickness larger than that of the drain electrode 14 and the source electrode 13. The two lateral portions 122 are formed on top faces of the source electrode 13 and the drain electrode 14, respectively. Each of the two lateral portions 122 has a top face located higher than a top face of the central portion 121, and a bottom face located between the top face and a bottom face of the central portion 121. A thickness of each of the two lateral portions 122 is larger than that of the source electrode 13 and the drain electrode 14, and less than that of the central portion 121. An edge face 123 is formed between and connects the top face of each of the two lateral portions 122 and the top face of the central portion 121. The edge face 123 is used to abruptly or smoothly connected the top faces of the central portion 121 and the two lateral portions 122. Each of the source electrode 13 and the drain electrode 14 has an outer end extending beyond a corresponding one of the two lateral portions 122 for connecting external electrical structures (not shown).

An atomic-doping layer 17 is formed in the channel layer 12. The dopant atom of the atomic-doping layer 17 may be made of In, Ga, Al, Sn, Zn, Eu, Er, Ce, Y, Gd, Lu, Si, Ge, N, O, H or other suitable materials. The atomic-doping layer 17 may be delta-doping with no more than one layer of atom. The addition of the atomic-doping layer 17 can increase the electrical conductivity of the channel layer 12. Alternatively, the thickness and the doping density of the atomic-doping layer 17 may also be changed to vary the electrical conductivity of the channel layer 12. The atomic-doping layer 17 includes a middle section 171, two end sections 172 and two connection sections 173 interconnecting the middle section 171 and the two end sections 172, respectively. The middle section 171 is parallel to the top face of the central portion 121 of the channel layer 12 as well as the top face of the substrate 11. The two end sections 172 are parallel to the middle section 171. The two end sections 172 are located higher than the middle section 171. Each of the two connection sections 173 is inclined relative to the middle section 171. Each of the connection section 171 extends gradually upwardly from the middle section 171 towards a corresponding one of the two end sections 172. The middle section 171 is embedded in the central portion 121 of the channel layer 12, and the two end sections 172 are embedded in the two lateral portions 122 of the channel layer 12, respectively. The atomic-doping layer 17 extends from a lateral side of the channel layer 12 to an opposite lateral side of the channel layer 12.

The insulative layer 16 covers the channel layer 12. The insulative layer 16 may be made of insulative materials such as SiO₂ or the like. The insulative layer 16 has a bottom connecting the top faces of the two lateral portions 122 and the central portion 121 and the vertical face 123 of the channel layer 12. The gate electrode 15 is formed on a flat top face of the insulative layer 16. The gate electrode 15 may be made of metal, polycrystalline silicon or other suitable materials. The gate electrode 15 is insulative from the source electrode 13 and the drain electrode 14 via the insulative layer 16. The gate electrode 15 can produce an electric filed acting on the channel layer 12, thereby conducting the source electrode 13 with the drain electrode 14 or insulating the source electrode 13 from the drain electrode 14. For an enhancement type of the thin film transistor 10, if a positive voltage applied to the gate electrode 15 exceeds a threshold voltage, the channel layer 12 becomes conductive so that the thin film transistor 10 is switched to an on status; if the positive voltage applied to the gate electrode 15 is less than the threshold voltage or no voltage is applied to the gate electrode 15, the channel layer 12 becomes insulative so that the thin film transistor 10 is switched to an off status. For a depletion type of the thin film transistor 10, if a negative voltage applied to the gate electrode 15 is less than a pinch-off voltage, the channel layer 12 becomes insulative so that the thin film transistor 10 is switched to the off status; if the negative voltage applied to the gate electrode 15 is larger than the pinch-off voltage or no voltage is applied to the gate electrode 15, the channel layer 12 becomes conductive so that the thin film transistor 10 is switched to the on status.

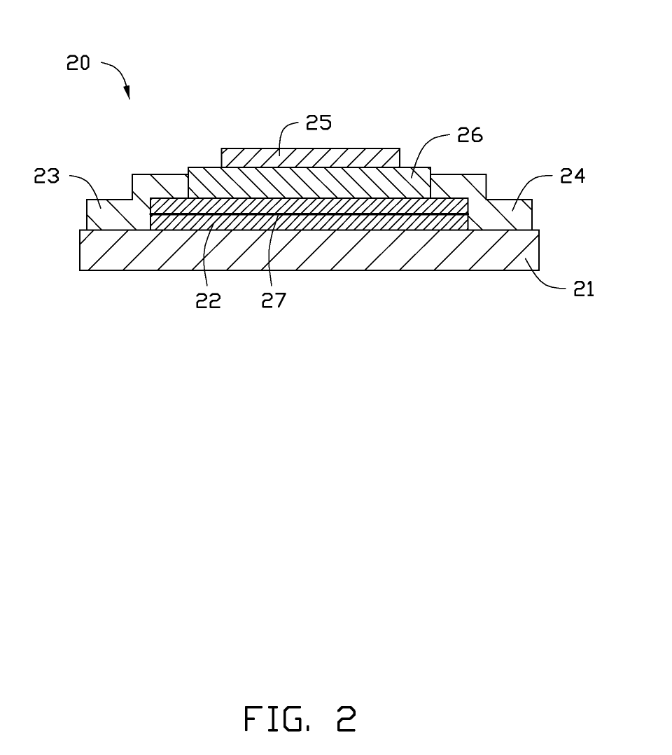

FIG. 2 shows a thin film transistor 20 similar to that shown in FIG. 1. The configurations of a source electrode 23, a drain electrode 24, a channel layer 22 and an insulative layer 26 shown in FIG. 2 are different from that shown in FIG. 1. Outer ends of the source electrode 23 and the drain electrode 24 are directly formed on a top face of a substrate 21. Inner ends of the source electrode 23 and the drain electrode 24 are directly formed on two opposite ends of the channel layer 22. An atomic-doping layer 27 is located lower than the inner ends of the source electrode 23 and the source electrode 23. The insulative layer 26 is formed between the inner ends of the source electrode 23 and the drain electrode 24. The insulative layer 26 connects the inner ends of the source electrode 23 and the drain electrode 24. A gate electrode 25 is formed on a top face of the insulative layer 26.

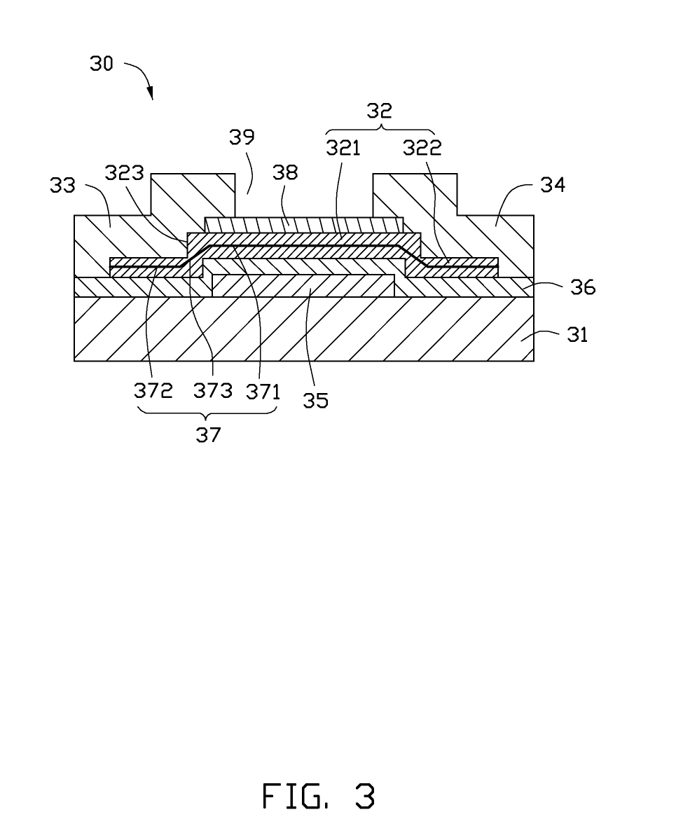

FIG. 3 shows a thin film transistor 30 in accordance with a third embodiment of the present disclosure. Similar to that shown in FIG. 1, the thin film transistor 30 shown in FIG. 3 also includes a substrate 31, a source electrode 33, a drain electrode 34, an insulative layer 36 and a gate electrode 35 except an etching stop layer 38. However, the positions of these elements shown in FIG. 3 are different from that shown in FIG. 1. The gate electrode 35 is directly formed at a central area of a top face of the substrate 31. The insulative layer 36 covers the gate electrode 35 and the other areas of the top face of the substrate 31. The insulative layer 36 is mostly covered by the channel layer 32 except two opposite ends thereof. The atomic-doping layer 37 is formed within the channel layer 32. Two lateral portions 322 of the channel layer 32 are located lower than a central portion 321. A edge face 323 is formed between a top face of each of the two lateral portions 322 and a top face of the central portion 321. A middle section 371 of the atom-doping layer 37 is parallel to two end sections 372. Two connection sections 373 wherein each of the two connections is inclined and extends downwardly from the middle section 371 towards a corresponding one of the two end sections 372. The top face of the central portion 321 of the channel layer 32 is mostly covered by the etching stop layer 38 except two opposite lateral ends thereof. The source electrode 33 and the drain electrode 34 cover top faces of the two opposite ends of the insulative layer 36, the two lateral portions 322 of the channel layer 32 and two opposite ends of the etching stop layer 38. A gap 39 is formed between the source electrode 33 and the drain electrode 34 to insulate the source electrode 33 and the drain electrode 34. The etching stop layer 38 is used to prevent etching liquid from etching the channel layer 32 when forming the gap 39 between the source electrode 33 and the drain electrode 34.

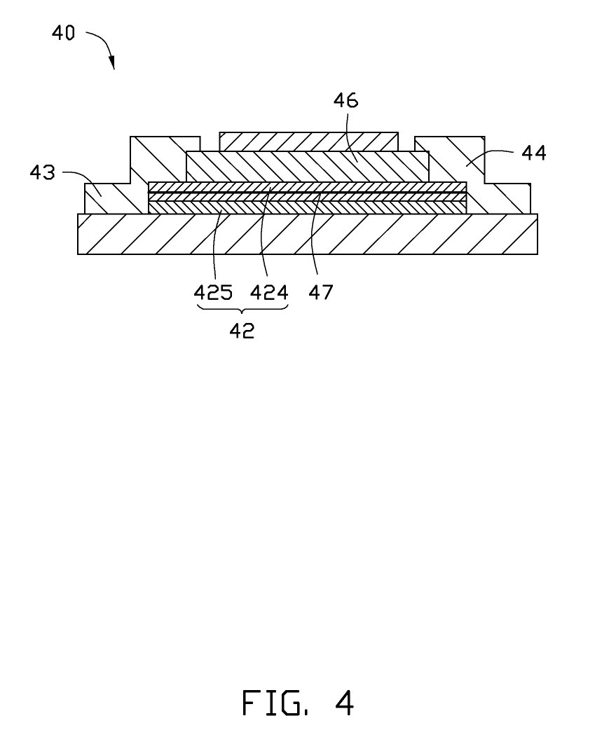

FIG. 4 shows a thin film transistor 40 similar to that shown in FIG. 2. The difference between the thin film transistors 10, 40 of FIG. 4 and FIG. 2 are that a source electrode 43 and a drain electrode 44 of FIG. 4 have inner ends covering two opposite ends of an insulative layer 46, and a channel layer 42 of FIG. 4 includes a first layer 424 and a second layer 425. The first layer 424 and the second layer 425 are both made of transparent conductive oxide semiconductor materials. A band gap of the first layer 424 is larger than that of the second layer 425. An atomic-doping layer 47 is embedded within the first layer 424. Alternatively, the band gap of the first layer 424 may also be less than that of the second layer 425, and the atomic-doping layer 47 is embedded within the second layer 425.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

1. A thin film transistor comprising:
a substrate;
a source electrode and a drain electrode spaced from the source electrode;
a channel layer connecting the source electrode with the drain electrode;
an insulative layer connecting the channel layer; and
a gate electrode connecting the insulative layer;
wherein an atomic-doping layer is formed in the channel layer.

2. The thin film transistor of claim 1, wherein the atom-doping layer is delta-doping with no more than one layer of atom.

3. The thin film transistor of claim 1, wherein the atomic-doping layer comprises a middle section, two end sections and two connection sections, each of the two connection sections being configured to connect each of the two end sections with the middle section.

4. The thin film transistor of claim 3, wherein the middle section of the atomic-doping layer is parallel to the two end sections.

5. The thin film transistor of claim 3, wherein each of the two connection sections is inclined relative to the middle section.

6. The thin film transistor of claim 5, wherein each of the two connection sections extends upwardly from the middle section towards each of the two end sections.

7. The thin film transistor of claim 5, wherein each of the two connection sections extends downwardly from the middle section towards each of the two end sections.

8. The thin film transistor of claim 3, wherein the channel layer comprises a central portion and two lateral portions, each of the two lateral portions being connected to the central portion, the middle section of the atomic-doping layer being embedded in the central portion of the channel layer, and each of the two end sections of the atomic-doping layer being embedded in each of the two lateral portions of the channel layer.

9. The thin film transistor of claim 8, wherein the source electrode and the drain electrode are directly formed on the substrate, the channel layer being directly connected to the substrate.

10. The thin film transistor of claim 9, wherein each of the two lateral portions of the channel layer covers each of an inner end of the source electrode and an inner end of the drain electrode.

11. The thin film transistor of claim 10, wherein the central portion and the two lateral portions of the channel layer are covered by the insulative layer.

12. The thin film transistor of claim 9, wherein each of the two lateral portions of the channel layer is covered by each of an inner end of the source electrode and an inner end of the drain electrode.

13. The thin film transistor of claim 12, wherein the central portion of the channel layer is covered by the insulative layer.

14. The thin film transistor of claim 8, wherein the gate electrode directly connects to the substrate, the insulative layer covers the gate electrode and directly connects to the substrate.

15. The thin film transistor of claim 14, wherein the channel layer is directly formed on the insulative layer, each of the source electrode and the drain electrode directly connects to and covers each of an end of the insulative layer and an end of the lateral portion of the channel layer.

16. The thin film transistor of claim 15 further comprising an etching stop layer formed between the source electrode and the drain electrode, wherein the etching stop layer directly connects to the channel layer.

17. The thin film transistor of claim 1, wherein the channel layer comprises a first layer and a second layer having a band gap larger than a band gap of the first layer, the atomic-doping layer being formed in the second layer.

18. The thin film transistor of claim 1, wherein the channel layer comprises a first layer and a second layer having a band gap larger than a band gap of the first layer, the atomic-doping layer being formed in the first layer.

19. The thin film transistor of claim 1, wherein the dopant of the atomic doping layer is selected from at least one of In, Ga, Al, Sn, Zn, Eu, Er, Ce, Y, Gd, Lu, Si, Ge, N, O, or H.

20. The thin film transistor of claim 1, wherein the channel layer is a transparent conductive oxide semiconductor material.
